(19) United States
(12) Patent Application Publication
(10) Pub. No.: US 2026/0149859 A1
(43) Pub. Date: May 28, 2026

(54) COOLED INFRARED CAMERA WITH INTEGRATED RADIATION SHIELDING

(71) Applicant: Raytheon Company, Tewksbury, MA (US)

(72) Inventors: Stephen Marinsek, Albuquerque, NM (US); Jesse C. Temkin, Tucson, AZ (US)

(21) Appl. No.: 18/962,787

(22) Filed: Nov. 27, 2024

(51) Int. Cl. H04N 23/52; G03B 17/55; H04N 23/20; H04N 23/51; H05K 9/00

(52) U.S. Cl. CPC H04N 23/52; G03B 17/55; H04N 23/20; H04N 23/51; H05K 9/0058; H05K 9/0081

(57) ABSTRACT

A radiation shielding structure includes multiple shielding elements configured to be enclosed within a housing assembly of a camera. The multiple shielding elements include first and second shielding elements. The first shielding element is configured to be placed over a set of cold components of the camera and includes a window opening to pass light. The set of cold components includes a sensor chip assembly (SCA) for detecting the light. The second shielding element is configured to be placed under the SCA and to connect to the first shielding element in order to form a chamber within which the set of cold components is enclosed.

### TECHNICAL FIELD

This disclosure relates generally to infrared cameras. More specifically, this disclosure relates to a cooled infrared camera with integrated radiation shielding.

### BACKGROUND

An infrared (IR) sensing element often needs to be protected from radiation in order to reduce or prevent degradation of the IR sensing element. The radiation could be artificial (manmade) or natural. Examples of artificial radiation may include X-rays (such as in medical diagnosis applications), radiation released in nuclear power production, or radiation from radioactive minerals in crushed rock, building materials, or phosphate fertilizers. Examples of natural radiation may include radiation in naturally-occurring radioactive minerals in the ground, soil, or water that produce background radiation and cosmic radiation from extremely-energetic particles from the sun and stars that enter Earth's atmosphere.

### SUMMARY

This disclosure relates to a cooled infrared camera with integrated radiation shielding.

In a first embodiment, a radiation shielding structure may include multiple shielding elements configured to be enclosed within a housing assembly of a camera. The multiple shielding elements may include first and second shielding elements. The first shielding element may be configured to be placed over a set of cold components of the camera and may include a window opening to pass light. The set of cold components may include a sensor chip assembly (SCA) for detecting the light. The second shielding element may be configured to be placed under the SCA and to connect to the first shielding element in order to form a chamber within which the set of cold components may be enclosed. The first shielding element and the second shielding element may not touch the set of cold components.

In a second embodiment, a cooled infrared camera with integrated radiation shielding may include a housing assembly, a set of cold components, and multiple radiation shielding elements. The set of cold components may include an SCA configured to detect light. The multiple radiation shielding elements may be configured to be enclosed within the housing assembly. The multiple radiation shielding elements may include first and second shielding elements. The first shielding element may be configured to be placed over the set of cold components and may include a window opening to pass the light. The second shielding element may be configured to be placed under the SCA and to connect to the first shielding element in order to form a chamber within which the set of cold components may be enclosed. The first shielding element and the second shielding element may not touch the set of cold components.

Any single one or any combination of the following features may be used with the first or second embodiment. The set of cold components may include a ceramic platform located under the SCA. The multiple radiation shielding elements may include a third shielding element configured to be placed under the ceramic platform. The second shielding element may include a first portion, a second portion, and a third portion that extends from a surface of the first portion to a surface of the second portion. The first portion may have a coin shape and may be configured to physically contact the ceramic platform. The second portion may have a ring shape spaced apart from the first portion and may be configured to attach to and annularly surround part of a cold finger of a cooling system. The set of cold components may include a cold shield configured to thermally insulate an interior space from the chamber and/or a cold filter configured to be placed within the interior space above the SCA. A gas evacuation channel may be formed by first protruding posts extending outward from an external surface of the first shielding element and/or second protruding posts extending outward from an external surface of the second shielding element. A gas evacuation channel may be formed by first evacuation channels recessed within the first shielding element and/or second evacuation channels recessed within the second shielding element. A set of Z-graded radiation shields may include (i) a first radiation shield that may include a first subset of the multiple shielding elements that has a first Z-grade and that may include the first shielding element and the second shielding element and (ii) a second radiation shield that may include a second subset of the multiple shielding elements that has a second Z-grade and that may include a third shielding element and a fourth shielding element. The second radiation shield may be configured to encapsulate the first radiation shield. From among the multiple shielding elements, at least one shielding element may be composed of a multi-ply Z-graded radiation shielding material in which multiple plies have different Z-values. The camera may include an infrared camera. The first shielding element may include a first annular notch configured to connect to a corresponding second annular notch of second shielding element, and the SCA may be configured to detect infrared energy.

In a third embodiment, a method may include providing multiple shielding elements configured to be enclosed within a housing assembly of a camera. The multiple shielding elements may include a first shielding element including a window opening to pass light, a second shielding element including a hole for a cold finger to pass through, and a third shielding element. The method may also include placing a window housing member of the housing assembly over the first shielding element. The method may further include placing the first shielding element over a set of cold components of the camera. The set of cold components may include an SCA for detecting the light. The method may also include placing the third shielding element under the SCA. The method may further include covering the hole of the second shielding element. In addition, the method may include installing the second shielding element under the third shielding element and in connection to the first shielding element to form a chamber within which the set of cold components may be enclosed.

Any single one or any combination of the following features may be used with the second embodiment. The method may include attaching the cold finger to the third shielding element. The method may include placing a third member of the housing assembly under the second shielding element. The method may include attaching the third member to the window housing member. The set of cold components may include a ceramic platform located under the SCA, and installing the second shielding element under the third shielding element may include installing the second shielding element under the ceramic platform.

Other technical features may be readily apparent to one skilled in the art from the following figures, descriptions, and claims.

### BRIEF DESCRIPTION OF THE DRAWINGS

For a more complete understanding of this disclosure and its advantages, reference is now made to the following description taken in conjunction with the accompanying drawings, in which like reference numerals represent like parts:

FIG. 1A illustrates an example infrared camera according to this disclosure;

FIG. 1B illustrates an example portion of the infrared camera of FIG. 1A according to this disclosure;

FIG. 2 illustrates an example infrared camera that includes a Z-graded radiation shield according to embodiments of this disclosure;

FIG. 3 illustrates an example top shield of FIG. 1A according to this disclosure;

FIG. 4 illustrates an example cold finger endcap of FIG. 1A according to this disclosure;

FIG. 5 illustrates an example bottom shield of FIG. 1A according to this disclosure;

FIGS. 6 and 7 illustrate example top and bottom shields that include recessed gas evacuation channels according to this disclosure;

FIGS. 8 and 9 illustrate example top and bottom shields that include protruding posts for creating gas evacuation channels according to this disclosure; and

FIG. 10 illustrates an example method for assembling a cooled infrared camera with an integrated radiation shielding structure according to this disclosure.

### DETAILED DESCRIPTION

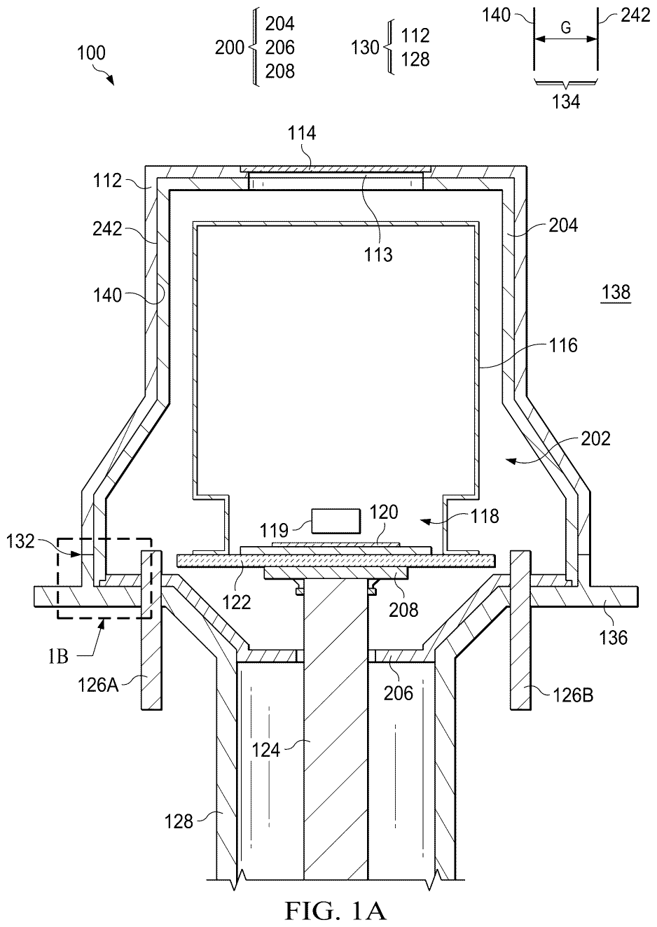

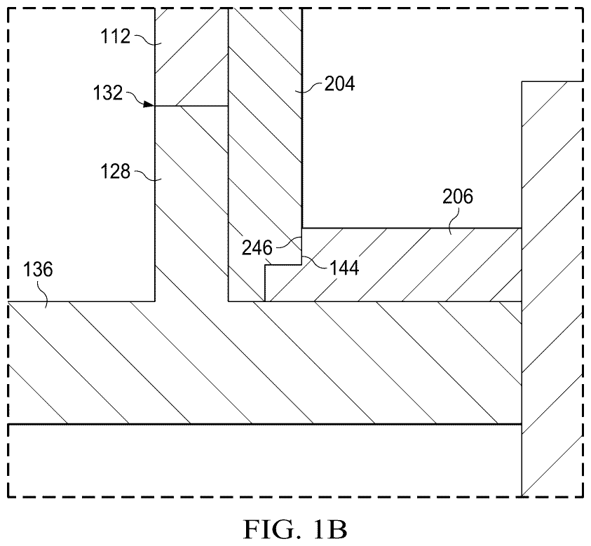

FIGS. 1 through 10, described below, and the various embodiments used to describe the principles of the present disclosure are by way of illustration only and should not be construed in any way to limit the scope of this disclosure. Those skilled in the art will understand that the principles of the present disclosure may be implemented in any type of suitably arranged device or system.

As noted above, an infrared (IR) sensing element often needs to be protected from radiation in order to reduce or prevent degradation of the IR sensing element. The radiation could be artificial (manmade) or natural. Examples of artificial radiation may include X-rays (such as in medical diagnosis applications), radiation released in nuclear power production, or radiation from radioactive minerals in crushed rock, building materials, or phosphate fertilizers. Examples of natural radiation may include radiation in naturally-occurring radioactive minerals in the ground, soil, or water that produce background radiation and cosmic radiation from extremely-energetic particles from the sun and stars that enter Earth's atmosphere.

Generally, an IR camera does not include radiation shielding that shields the IR sensing element from radiation. In a use case where there is a need or desire to shield an IR camera from radiation, the IR camera can be inserted into a box composed of one or more materials having radiation shielding properties. In these cases, the radiation shielding box is located outside of the housing of the IR camera. That is, the dimensions of the radiation shielding box are large enough to surround the housing of the IR camera. The housing of the IR camera typically houses internal component of the IR camera, such as the IR sensing element. The separation distance between the IR sensing element and the radiation shielding box typically varies directly with the level of protection provided. As a result, when the shielding material is further from the IR sensing element, more mass of radiation shielding material is needed for a given level of protection. This is because the mass of the radiation shielding material is roughly proportional to squared radial distance, which can be expressed as m_{shielding}∝ r².

This disclosure provides a cooled infrared camera with integrated radiation shielding. Among other things, this disclosure recognizes that mass reduction can be achieved by integrating radiation shielding with an infrared camera. For example, this disclosure provides an IR camera with internal integrated ionizing radiation shielding. Among other things, the radiation shielding described in this disclosure may provide protection for a sensor chip and interconnection inside a dewar housing. These approaches result in a reduction in system weight by bringing an equivalent thickness of shielding closer to a focal plane array or other sensors. Also, in some embodiments, shielding elements can be nested, such as to support a z-graded configuration.

FIG. 1A illustrates an example infrared (IR) camera 100 according to this disclosure, and FIG. 1B illustrates an example portion of the IR camera 100 of FIG. 1A according to this disclosure. More specifically, FIG. 1A illustrates a longitudinal cross-sectional view of the IR camera 100, and FIG. 1B illustrates a portion of the IR camera 100 that includes an internal radiation shield 200 forming a radiation-shielded chamber 202 internally within the IR camera 100.

As shown in FIG. 1A, the IR camera 100 includes a window housing 112, a window optic 114, a cold shield 116, an interior space 118 within the cold shield 116 (which could include a cold filter 119 or other component(s)), a sensor chip assembly (SCA) 120, a ceramic platform 122, a cold finger 124, one or more feed-through connectors 126a-126b, and a lower housing assembly 128. The window housing 112 and the lower housing assembly 128 can be attached to form a housing assembly 130. In some cases, the window housing 112 and the lower housing assembly 128 can be welded together at a weld joint, and the weld joint may be referred to as weld 132. The top side of the window housing 112 may include a recess that fits the window optic 114, such as when dimensions and contours of the recess correspond to the thickness and exterior surfaces of the window optic 114. The top side of the window housing 112 may include a hole 113 beneath the recess. In some cases, the hole 113 may be concentric with the recess and may have a diameter that is less than the diameter of the window optic 114.

The SCA 120 can be configured to detect infrared energy that enters through the window optic 114 and generate a corresponding electric signal, which can be carried through the feed-through connectors 126a-126b. In some cases, the SCA 120 may represent a point-of-reference for the IR camera, such as when the front portion of the IR camera 100 starts at the SCA 120 and extends frontward toward the window optic 114 and when the back portion of the IR camera 100 starts at the SCA 120 and extends in an opposite direction away from the window optic 114 (backward toward the ceramic platform 122 or cold finger 124).

The cold finger 124 can include a bore extending longitudinally. In some cases, the cold finger 124 can have the shape of a hollow cylinder, such as a straw with a flat end. A localized cold surface can be generated at the flat end of the cold finger 124 in order to remove heat from at least some of the components of the IR camera 100. In some embodiments, cold components of the IR camera 100 can include the cold shield 116, the cold filter 119, or other component(s) within the interior space 118, the SCA 120, and the ceramic platform 122.

The housing assembly 130 can form an interior space 134, and the internal radiation shield 200 can be provided inside the interior space 134 of the housing assembly 130. That is, the IR camera 100 can be constructed as a cooled IR camera with one or more integrated radiation shielding elements, such as by integrating the internal radiation shield 200 within the IR camera 100. An external environment 138 outside the housing assembly 130 is external to the internal radiation shield 200 and is therefore outside of both the internal radiation shield 200 and the housing assembly 130.

As shown in FIG. 1B, the internal radiation shield 200 includes a top shield 204, a bottom shield, 206, and a cold finger endcap 208. The top shield 204 and bottom shield 206 can operate at ambient temperatures, such as warmer temperatures. The cold finger endcap 208 can operate at cryogenically cooled temperatures, such as temperatures cooled by a cryogenic cooler. Embodiments of this disclosure may reduce or minimize cooled parts from contacting uncooled parts and may thermally insulate cooled space from uncooled space, thereby reducing or preventing heat creeping in or heat transferring to the cryogenically cooled space and parts, such as the interior space 118, the cold components of the IR camera 100, and the cold finger endcap 208. For example, the top shield 204 and bottom shield 206 may not contact the ceramic platform 122, at least in part because too long of a period of time would be consumed to cool the top shield 204 and bottom shield 206 to the cryogenically cooled temperatures. In some embodiments, the top shield 204 and bottom shield 206 may not contact any cryogenically cooled space and parts, such as the interior space 118, the cold components of the IR camera 100, and the cold finger endcap 208. For instance, the cold finger endcap 208 may provide radiation shielding to the cold finger 124 without touching uncooled parts.

Embodiments of this disclosure can reduce or minimize mass held at or operating at cryogenic temperatures. For example, the top shield 204 can be positioned above to fit over the cold shield 116 without touching the cold shield 116. Similarly, the bottom shield 206 can be positioned below the cold shield 116 without touching the cold shield 116. As another example, a flange of the cold shield 116 can be bonded to a top surface of the ceramic platform 122 to seal the cooled interior space 118 from the chamber 202, and the cold shield 116 can be configured to thermally insulate the interior space 118 from the chamber 202.

The interior space 134 of the housing assembly 130 can be defined or bounded at least in part by interior surfaces 140 of the housing assembly 130 on various sides. The internal radiation shield 200 can be provided in close proximity to the interior surfaces 140 and may be in surface-to-surface contact with the interior surfaces 140 of the housing assembly 130. Any gap G that extends from an interior surface 140 of the housing assembly 130 to an exterior surface 242 of the top and bottom shields 204-206 may be wide enough for a small amount of vacuum space. In some cases, most or all of the interior space 134 is occupied by the internal radiation shield 200.

The top shield 204 and the bottom shield 206 can be joined to each other. In some cases, a half-lap joint can be used, where a perimeter of the bottom of the top shield 204 intersects a perimeter of the top of the bottom shield 206. To form the half-lap joint, the perimeter of the bottom of the top shield 204 can include a first notch 144 that fits into a corresponding second notch 246 at the perimeter of the top of the bottom shield 206. Note that notches of various shapes and sizes can be used here. The use of the notches 144 and 246 may be beneficial since the use of a full lap joint (having the shape of a straight line) could provide a path through which unwanted radiation from the external environment 138 could enter the chamber 202. The unwanted radiation could therefore penetrate the housing assembly 130, cross the interior space 134, and enter and propagate though the straight path of the joint between the top and bottom shields 204 and 206. The overlapping notches 144 and 246 here can reduce or prevent the internal radiation shield 200 from including any straight path into the chamber 202, thereby providing radiation shielding material along every straight path. That is, the overlapping notches 144 and 246 reduce or prevent the creation of a window for unwanted radiation.

In some embodiments, the feed-through connectors 126a-126b can be ceramic and have a lateral cross-section that is rectangular. The feed-through connectors 126a-126b extend from the chamber 202 through an opening, a flange of the bottom shield 206, and a corresponding opening (such as a hole) through a flange portion 136 of the lower housing assembly 128 to the external environment 138. In the example shown, the external environment 138 is outside of both the radiation shield 200 and the housing assembly 130.

A mass of the IR camera 100 can depend at least partially upon and can be proportional to the distance from the housing assembly 130 to the SCA 120. Thus, closer positions of the housing material to the SCA 120 can reduce the mass of the IR camera 100. In some embodiments, the housing assembly 130 can be composed of an uncommon metal. The material of the housing assembly 130 can be suitable for welding or other attachment so that the window housing 112 and the lower housing assembly 128 can be joined. In some cases, the top shield 204 can be placed inside the interior space of the window housing 112 before the weld 132 is created during manufacturing. The welding process at the location of the weld 132 during manufacturing could generate high temperatures, and heat from the process of creating the weld 132 can be transferred from the material of the housing assembly 130 to the shielding material of the internal radiation shield 200. In light of this heat transfer, a material for the housing assembly 130 can be selected so as to not deform the shielding material of the internal radiation shield 200. Thus, for instance, the material of the housing assembly 130 may have a controlled coefficient of thermal expansion (CTE). Also, the housing assembly 130 can be designed to maintain hermeticity (remain hermetically sealed) over an operational lifetime (such as 8, 15, or 35 years). In order for the housing assembly 130 to achieve these performance metrics, the material of the housing assembly 130 may be different from the radiation shielding material. As particular examples, the internal radiation shield 200 can be composed of at least one radiation shielding material, such as tantalum (Ta), tin (Sn), copper (Cu), aluminum (Al), or a metal alloy such as steel.

The shape(s) of the exterior surface(s) 242 of the top and bottom shields 204-206 can match the interior surface(s) 140 of the housing assembly 130. In some embodiments, walls of the internal radiation shield 200 have a uniform thickness such that the shapes of the interior and exterior surfaces of the internal radiation shield 200 are the same as and concentric with each other. Note, however, that the radiation shielding material and its thickness may be selected based on particular needs for a given application and can easily vary.

A mass of the internal radiation shield 200 can depend at least partially upon and can be proportional to its distance from the cold components of the IR camera 100. In order to reduce or minimize the mass of the internal radiation shield 200, the radiation shielding material could be placed as close as possible to the cold components of the IR camera 100.

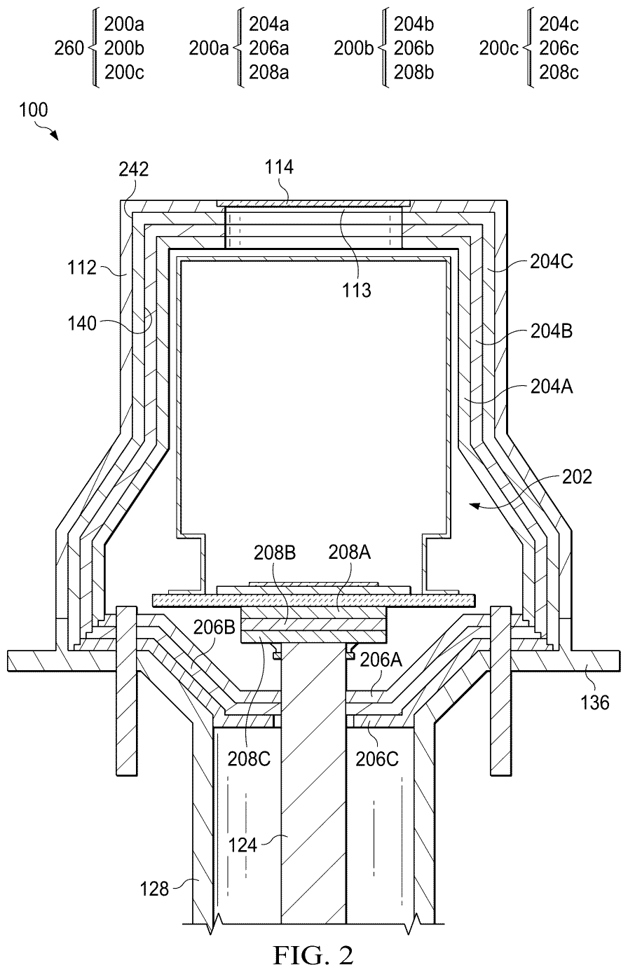

FIG. 2 illustrates an example infrared camera that includes a Z-graded radiation shield 260 according to embodiments of this disclosure. As shown in FIG. 2, the infrared camera includes the Z-graded radiation shield 260. In some embodiments, the Z-graded radiation shield 260 includes multiple radiation shields 200a-200c may be nested according to a Z-graded shield design. The phrase “Z-graded” refers to the atomic number of the radiation shielding material, since the atomic number is also referred to as a Z-grade or Z-value. In some cases, nested radiation shields 200a-200c can have decreasing mass densities. For example, the outermost radiation shield (such as the third radiation shield 200c) may be composed of a radiation shielding material that is the heaviest and that has the largest atomic number (Z), such as when formed using tungsten (W). The middle radiation shielding material may be composed of a radiation shielding material that is lighter and that has a smaller atomic number, such as when formed using tantalum. The innermost radiation shielding material may be composed of a radiation shielding material that is the lightest and that has the smallest atomic number, such as when formed using aluminum. The adjacent radiation shields can be assembled and attached to each other in any suitable manner, such as by using high-strength low-outgassing adhesive.

As another example, each of one or more internal radiation shields 200 can be composed of radiation shielding material that is multi-ply, such as when the radiation shielding material is formed by plating. A multi-ply radiation shielding material could potentially also be formed to have a Z-graded shield design in which the multiple plies have different Z-values. In some embodiments, the internal radiation shield 200 may be composed of a tri-ply radiation shielding material, which can be formed by providing a first layer composed of a first radiation shielding material (such as aluminum), performing a plating process to deposit a second radiation shielding material (such as tantalum) as a second layer onto an exterior surface of the first layer, and performing another plating process to deposit a third radiation shielding material (such as tungsten) as a third layer onto the second layer. The multi-ply radiation shielding material could look quite similar to the nested radiation shields 200a-200c, wherein a difference would be no physical separation of layers. The separation between nested radiation shields 200a-200c is difficult to illustrate due to being quite small compared to the size of the components 204a-204c, 206a-206c, and 208a-208c. For ease of illustration, the first, second, and third layers of the multi-ply radiation shielding material can be represented by the radiation shields 200a, 200b, and 200c, respectively.

FIG. 3 illustrates an example top shield 204 of FIG. 1A according to this disclosure. As shown in FIG. 3, the top side of the top shield 204 can include a hole 302, which may be concentric with the hole 113 in the top side of the window housing 112. A diameter of the hole 302 may be substantially similar to the diameter of the hole 113 in the top side of the window housing 112. A wedge is cut out in FIG. 3 for ease of illustrating contours of an interior surface 304 of the top shield 204 and a thickness between the exterior surface 242 and interior surface 304. The first notch 144 is also shown. The top shield 204 provides shielding coverage (such as coverage from radiation) for the forward portion of the IR camera 100, and the hole 302 represents an opening for incoming light.

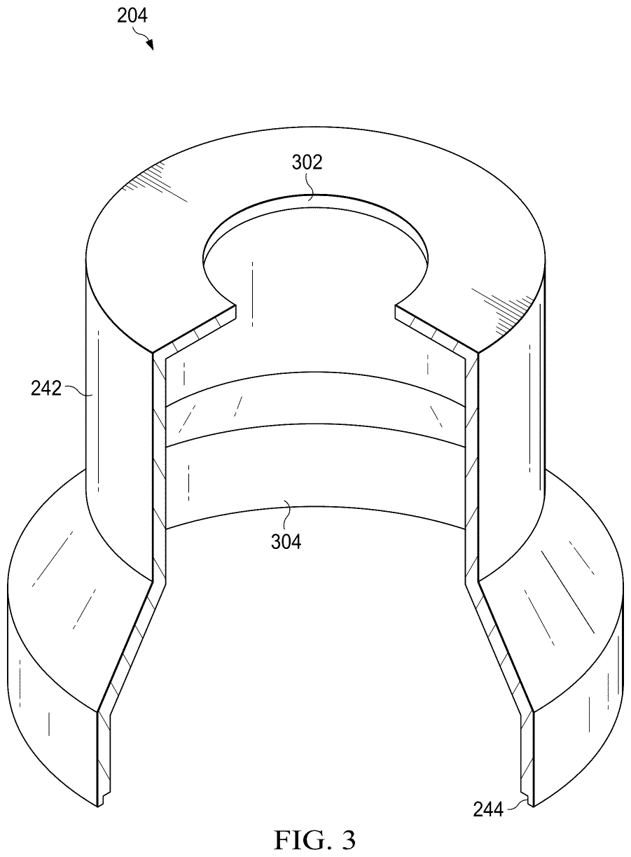

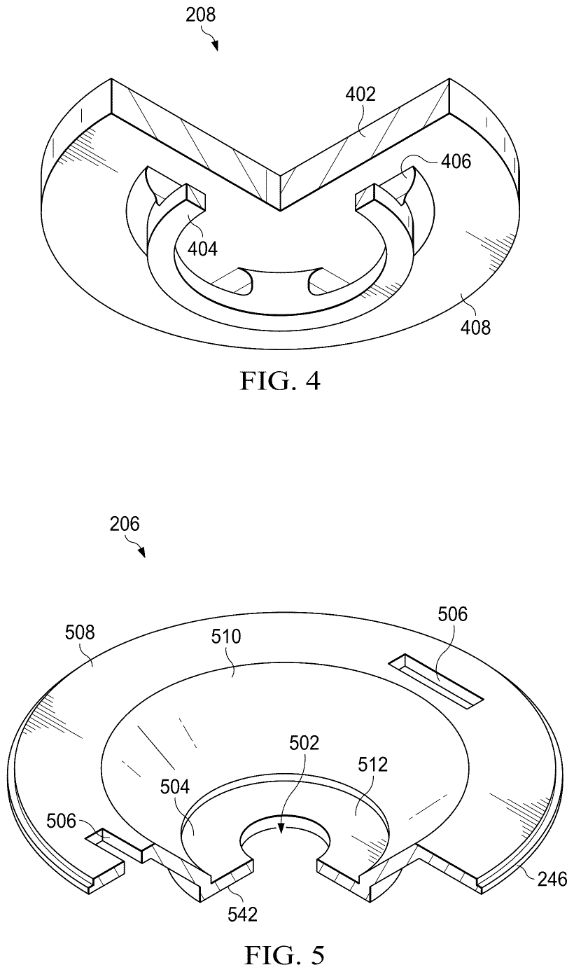

FIG. 4 illustrates an example cold finger endcap 208 of FIG. 1A according to this disclosure. As shown in FIG. 4, the cold finger endcap 208 can include an upper portion 402, a lower portion 404, and a middle portion 406 that extends from a bottom surface 408 of the upper portion 402 to a top surface of the lower portion 404. In some embodiments, the cold finger endcap 208 represents a unitary solid piece conceptually divided into these portions 402, 404, 406. In other embodiments, these portions 402, 404, 406 represent separate components that are connected to each other to form the cold finger endcap 208. The cold finger endcap 208 can provide coverage for radiation traveling through a bore for the cold finger 124. The cold finger endcap 208 can also add thermal mass if a dense material is used as the radiation shielding material.

In the illustrated example, the upper portion 402 of the cold finger endcap 208 can have a flat coin shape. The upper portion 402 can be a localized cold surface that enables cooling of the cold components of the IR camera 100. For example, a top surface of the upper portion 402 may physically contact the ceramic platform 122. The lower portion 404 of the cold finger endcap 208 is spaced apart from the upper portion 402 and may have a ring shape. For instance, a cross section of the ring shape could be rectangular.

In some embodiments, the top end of the cold finger 124 is not placed in solid mechanical contact (such as surface-to-surface contact) with the upper portion 402 of the cold finger endcap 208 because vibrations can occur during operation. These vibrations could cause the top end of the cold finger 124 to collide with adjacent surfaces (such as the bottom surface 408), and such collisions can wear and deteriorate the adjacent surfaces. In some embodiments, the lower portion 404 of the cold finger endcap 208 can be attached to and annularly surround the top end of the cold finger 124. The height of the middle portion 406 can represent a separation distance from the top end of the cold finger 124 and the bottom surface 408. The inner diameter of the lower portion 404 can fit or be substantially equivalent to the outer diameter of the cold finger 124.

FIG. 5 illustrates an example bottom shield 206 of FIG. 1A according to this disclosure. As shown in FIG. 5, the bottom shield 206 can include a hole 502, an interior surface 504, one or more openings 506, and an exterior surface 542. The exterior surface 242 of the radiation shield 200 can include the exterior surface 542 of the bottom shield 206 and the exterior surface of the top shield 204 as shown in FIG. 3. A wedge is cut out in FIG. 5 for ease of illustrating contours of the interior surface 504 of the bottom shield 206 and a thickness between the exterior and interior surfaces 542 and 504. The second notch 246 is also shown.

In some embodiments, the bottom shield 206 can be a unitary piece conceptually divided into an upper portion 508, a middle portion 510, and a lower portion 512. The lower portion 512 can include the hole 502, which can be concentric with the ring-shaped lower portion 404. In some cases, the lower portion 512 can have the shape of a flat coin with the hole 502 cut from the center. The hole 502 can fit or be substantially equivalent to the outer diameter of the cold finger 124. The diameter of the hole 302 can be substantially equivalent to the outer diameter of the cold finger 124. In some cases, the middle portion 510 can have the shape of a conical funnel with (i) a bottom rim that has a first diameter where the middle portion intersects the lower portion of the bottom shield 206 and (ii) a top rim that has a larger second diameter where the middle portion intersects the top surface of the upper portion 508. The top surface of the bottom shield 206 may also represent the top surface of the upper portion 508. In some cases, the upper portion 508 can be an annular flange that extends outward from the top rim of the middle portion 510 to the notch 246. The one or more openings 506 can represent one or more holes through the upper portion 508. The feed-through connectors 126a-126b may pass through the opening(s) 506 between the chamber 202 and the external environment 138.

The bottom shield 206 can provide coverage (such as shielding from radiation) for the back portion of the IR camera 100. In some embodiments, the opening(s) 506 can be placed so that there is no direct unshielded path for the propagation of radiation to the focal plane array. The opening(s) 506 and feed-through connectors 126a-126b can also be thermally isolated from the cold finger 124 and therefore may not add to the thermal mass of the IR camera 100.

Although FIGS. 2 through 5 illustrate an example of an internal radiation shield 200, various changes may be made to FIGS. 2 through 5. For example, various components in FIGS. 2 through 5 could be combined, further subdivided, or omitted and additional components could be added according to particular needs. As a particular example, the IR camera 100 may include multiple internal radiation shields 200, such as nested radiation shields 200 (one inside another). As particular examples, a first radiation shield 200a may be placed inside of and encapsulated by a second radiation shield 200b, and optionally the second radiation shield 200b may be placed inside of and encapsulated by a third radiation shield 200c.

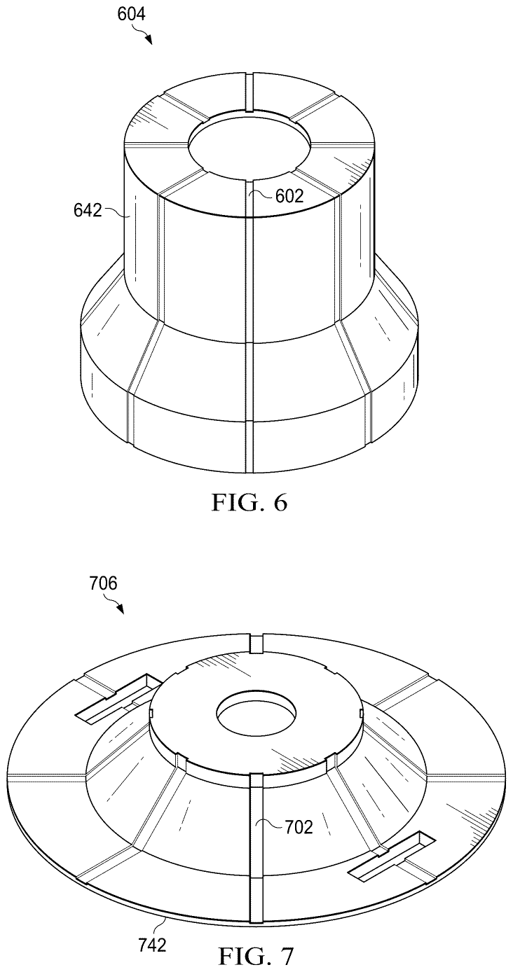

FIGS. 6 and 7 illustrate example top and bottom shields 604 and 706 that include recessed gas evacuation channels according to this disclosure. In some embodiments, a vacuum pump may be connected to the IR camera 100 to remove gas molecules down to a specified vacuum pressure. Gas evacuation channels 602 and 702 can optionally be used to provide a wider exit path than the narrow gap G described above, thus providing for faster removal of gas molecules. The duration of time that the vacuum pump operates to remove gas from the interior space 134 depends upon an amount of energy the vacuum pump expends to force the gas molecules to traverse an exit path out of the interior space 134. Without the gas evacuation channels 602 and 702, the vacuum pump expends more energy to force gas molecules through the gap G between the housing assembly 130 and the radiation shield 200. This first amount of energy expended during a first period of time the vacuum pump operates. With the gas evacuation channels 602 and 702, the vacuum pump expends less energy and time to remove gas from the interior space 134.

As shown in FIG. 6, the evacuation channels 602 represent recesses cut out from or otherwise formed in the exterior surface 642 of the top shield 604 to create spaces wider than the gap G for removing gas from the IR camera 100. Similarly, as shown in FIG. 7, the evacuation channels 702 represent recesses cut out from or otherwise formed in the exterior surface 742 of the bottom shield 706 to create spaces wider than the gap G. The second evacuation channels 702 may correspond to and align with the first evacuation channels 602.

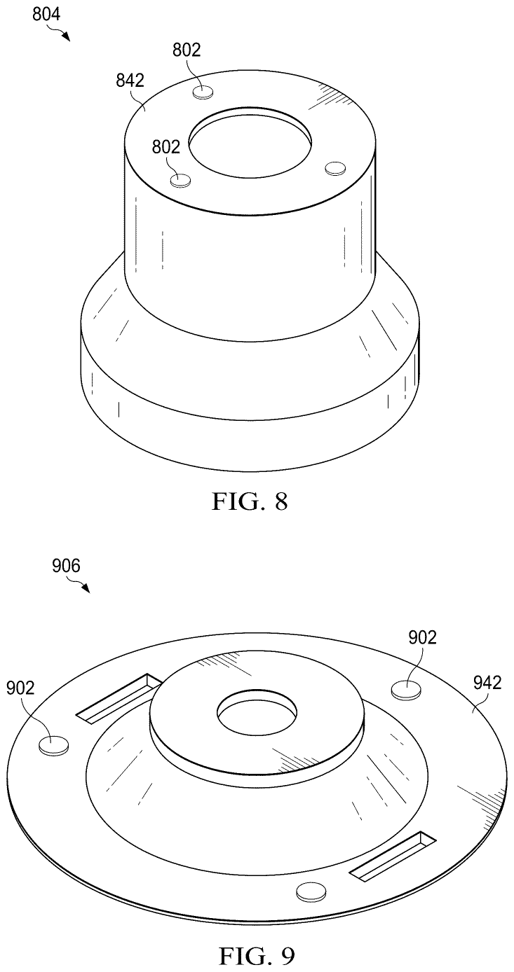

FIGS. 8 and 9 illustrate example top and bottom shields 804 and 906 that include protruding posts 802 and 902 for creating gas evacuation channels according to this disclosure. The protruding posts 802 and 902 extend outward from the external surfaces of the top and bottom shields 804 and 906 and extend toward and contact the internal surfaces 140 of the housing assembly 130. As shown in FIG. 8, the protruding posts 802 create at least one gas evacuation channel between the internal surface 140 of the housing assembly 130 and an external top surface 842 of the top shield. The at least one gas evacuation channel created by the protruding posts 802 can be wider than the gap G by a distance that is at least the height of the protruding posts 802. Similarly, as shown in FIG. 9, the protruding posts 902 create at least one gas evacuation channel between the internal surface 140 of the housing assembly 130 and an external bottom surface 942 of the bottom shield 906. Again, the at least one gas evacuation channel created by the protruding posts 902 can be wider than the gap G by a distance that is at least the height of the protruding posts 902.

Although FIGS. 6 through 9 illustrate example approaches for forming gas evacuation channels, various changes may be made to FIGS. 6 through 9. For example, gas evacuation channels may be formed in any suitable manner or may be excluded depending on the implementation.

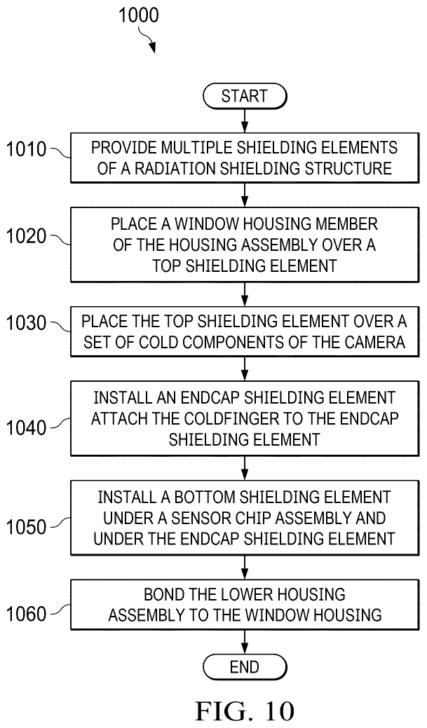

FIG. 10 illustrates an example method 1000 for assembling a cooled infrared camera with an integrated radiation shielding structure according to this disclosure. For ease of explanation, the method 1000 is described as being used to assemble the cooled IR camera 100 with the internal radiation shield 200. However, the method 1000 may be used to assemble any suitable cooled infrared camera with any suitable integrated radiation shielding structure.

At block 1010, multiple shielding elements of a radiation shielding structure are provided. The multiple shielding elements can be configured to be enclosed within the housing assembly 130 of the IR camera 100. The multiple shielding elements can include a first shielding element (such as a top shield 204, 604, 804) and can include a window opening to pass light. The multiple shielding elements can also include a second shielding element (such as the bottom shield 206, 706, 906) and a third shielding element (such as the cold finger endcap 208).

At block 1020, a window housing member (such as the window housing 112) of the housing assembly 130 is placed over the first shielding element. For example, the first shielding element can be inserted into an interior space of the window housing 112. As a particular example, the first shielding element may be installed into the interior space 134 of the housing assembly 130. In some embodiments supporting a Z-graded shield design, multiple top shields may be inserted in order from largest outermost to smallest innermost. The top portion of an outermost radiation shield may be adhered or otherwise attached to the interior surface 140 of the window housing 112, and the top shields corresponding to other radiation shields may be adhered or otherwise attached to other radiation shields. In other embodiments supporting a Z-graded shield design, the top shield 204 may be composed of a multi-ply radiation shielding material, such as a tungsten-tantalum-aluminum tri-ply. At block 1030, the first shielding element is placed over a set of cold components of the camera. For example, the cold components of the IR camera 100 may be inserted into a chamber 202 that is at least partially bounded by walls of the first shielding element.

At block 1040, a third shielding element is installed below the ceramic platform 122. In some embodiments, the third shielding element may be bonded or fastened to the ceramic platform 122. The third shielding element may be placed under the SCA 120, and the hole 502 of the second shielding element may be covered here. For example, the cold finger endcap 208 may be placed under the ceramic platform 122 located under the SCA 120. In some embodiments of block 1040, the cold finger 124 is attached (such as bonded or fastened) to the third shielding element. As a particular example, the lower portion 404 of the cold finger endcap 208 can be attached to and annularly surround the top end of the cold finger 124 such that the top end of the cold finger 124 is spaced apart from the bottom surface 408 of the upper portion 402 of the cold finger endcap 208.

At block 1050, the second shielding element is installed under the third shielding element that is under the SCA 120 and in connection to the first shielding element to form a chamber within which the set of cold components is enclosed. In some examples, the second shielding element may be bonded or fastened to the interior surface of the lower housing assembly 128. In some cases, the upper portion 508 of the bottom shield 206 may be bonded or fastened to the interior surface of the flange portion 136 of the lower housing assembly 128. The openings 506 of the bottom shield 206 can be aligned with corresponding openings through the flange portion 136. The second notches 246 of the bottom shield 206 can be aligned with and physically coupled to the first notches 144 of the top shield 204. At block 1060, the lower housing assembly 128 is placed under the second shielding element and is bonded to the window housing 112. For example, a weld 132 may be created annularly.

Although FIG. 10 illustrates one example of a method 1000 for assembling a cooled infrared camera with an integrated radiation shielding structure, various changes may be made to FIG. 10. For example, while shown as a series of steps, various steps in FIG. 10 could overlap, occur in parallel, occur in a different order, or occur any number of times. As a particular example, the method 1000 can have a different order, starting at block 1010 to provide multiple shielding elements of a radiation shielding structure, then sequentially proceeding through blocks 1050, 1040, 1030, 1020, 1060. In this example, at block 1050, a bottom shielding element can be installed under a sensor chip assembly. At block 1040, an endcap shielding element can be installed. At block 1030, the top shielding element can be placed over a set of cold components. At block 1020, a window housing member of the housing assembly can be placed over a top shielding element. At block 1060, the lower housing assembly can be bonded to the window housing.

It may be advantageous to set forth definitions of certain words and phrases used throughout this patent document. The term “couple” and its derivatives refer to any direct or indirect communication between two or more components, whether or not those components are in physical contact with one another. The terms “include” and “comprise,” as well as derivatives thereof, mean inclusion without limitation. The term “or” is inclusive, meaning and/or. The phrase “associated with,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, have a relationship to or with, or the like. The phrase “at least one of,” when used with a list of items, means that different combinations of one or more of the listed items may be used, and only one item in the list may be needed. For example, “at least one of: A, B, and C” includes any of the following combinations: A, B, C, A and B, A and C, B and C, and A and B and C.

The description in the present disclosure should not be read as implying that any particular element, step, or function is an essential or critical element that must be included in the claim scope. The scope of patented subject matter is defined only by the allowed claims. Moreover, none of the claims invokes 35 U.S.C. § 112(f) with respect to any of the appended claims or claim elements unless the exact words “means for” or “step for” are explicitly used in the particular claim, followed by a participle phrase identifying a function. Use of terms such as (but not limited to) “mechanism,” “module,” “device,” “unit,” “component,” “element,” “member,” “apparatus,” “machine,” “system,” “processor,” or “controller” within a claim is understood and intended to refer to structures known to those skilled in the relevant art, as further modified or enhanced by the features of the claims themselves, and is not intended to invoke 35 U.S.C. § 112(f).

While this disclosure has described certain embodiments and generally associated methods, alterations and permutations of these embodiments and methods will be apparent to those skilled in the art. Accordingly, the above description of example embodiments does not define or constrain this disclosure. Other changes, substitutions, and alterations are also possible without departing from the spirit and scope of this disclosure, as defined by the following claims.

What is claimed is:

1. A radiation shielding structure comprising:
multiple shielding elements configured to be enclosed within a housing assembly of a camera, wherein the multiple shielding elements include:
a first shielding element configured to be placed over a set of cold components of the camera and including a window opening to pass light, the set of cold components including a sensor chip assembly (SCA) for detecting the light; and
a second shielding element configured to be placed under the SCA and to connect to the first shielding element in order to form a chamber within which the set of cold components is enclosed, wherein first shielding element and the second shielding element do not touch the set of cold components.

2. The radiation shielding structure of claim 1, wherein:
the set of cold components includes a ceramic platform located under the SCA; and
the multiple radiation shielding elements further include a third shielding element configured to be placed under the ceramic platform.

3. The radiation shielding structure of claim 2, wherein the third shielding element comprises:
a first portion having a coin shape and configured to physically contact the ceramic platform;
a second portion having a ring shape spaced apart from the first portion and configured to attach to and annularly surround part of a cold finger of a cooling system; and
a third portion that extends from a surface of the first portion to a surface of the second portion.

4. The radiation shielding structure of claim 2, wherein the set of cold components further includes at least one of:
a cold shield configured to thermally insulate an interior space from the chamber; or
a cold filter configured to be placed within the interior space above the SCA.

5. The radiation shielding structure of claim 1, further comprising a gas evacuation channel formed by at least one of:
first protruding posts extending outward from an external surface of the first shielding element; and
second protruding posts extending outward from an external surface of the second shielding element.

6. The radiation shielding structure of claim 1, further comprising a gas evacuation channel formed by at least one of:
first evacuation channels recessed within the first shielding element; and
second evacuation channels recessed within the second shielding element.

7. The radiation shielding structure of claim 1, further comprising a set of Z-graded radiation shields including:
a first radiation shield that includes a first subset of the multiple shielding elements that has a first Z-grade and that includes the first shielding element and the second shielding element; and
a second radiation shield that includes a second subset of the multiple shielding elements that has a second Z-grade and that includes a third shielding element and a fourth shielding element; and
wherein the second radiation shield is configured to encapsulate the first radiation shield.

8. The radiation shielding structure of claim 1, wherein, from among the multiple shielding elements, at least one shielding element is composed of a multi-ply Z-graded radiation shielding material in which multiple plies have different Z-values.

9. The radiation shielding structure of claim 1, wherein:
the first shielding element includes a first annular notch configured to connect to a corresponding second annular notch of second shielding element; and
the SCA is configured to detect infrared energy.

10. A camera comprising:
a housing assembly;
a set of cold components including a sensor chip assembly (SCA) configured to detect light; and
multiple radiation shielding elements configured to be enclosed within the housing assembly, wherein the multiple radiation shielding elements include:
a first shielding element configured to be placed over the set of cold components and including a window opening to pass the light; and
a second shielding element configured to be placed under the SCA and to connect to the first shielding element in order to form a chamber within which the set of cold components is enclosed, wherein first shielding element and the second shielding element do not touch the set of cold components.

11. The camera of claim 10, wherein:
the set of cold components includes a ceramic platform located under the SCA; and
the multiple radiation shielding elements further include a third shielding element configured to be placed under the ceramic platform.

12. The camera of claim 11, wherein the second shielding element comprises:
a first portion having a coin shape and configured to physically contact the ceramic platform;
a second portion having a ring shape spaced apart from the first portion and configured to attach to and annularly surround part of a cold finger of a cooling system; and
a third portion that extends from a surface of the first portion to a surface of the second portion.

13. The camera of claim 11, wherein the set of cold components further includes at least one of:
a cold shield configured to thermally insulate an interior space from the chamber; or
a cold filter configured to be placed within the interior space above the SCA.

14. The camera of claim 10, further comprising a gas evacuation channel formed by at least one of:
first protruding posts extending outward from an external surface of the first shielding element; and
second protruding posts extending outward from an external surface of the second shielding element.

15. The camera of claim 10, further comprising a gas evacuation channel formed by at least one of:
first evacuation channels recessed within the first shielding element; and
second evacuation channels recessed within the second shielding element.

16. The camera of claim 10, further comprising a set of Z-graded radiation shields including:
a first radiation shield that includes a first subset of the multiple shielding elements that has a first Z-grade and that includes the first shielding element and the second shielding element; and
a second radiation shield that includes a second subset of the multiple shielding elements that has a second Z-grade and that includes a third shielding element and a fourth shielding element; and
wherein the second radiation shield is configured to encapsulate the first radiation shield.

17. The camera of claim 10, wherein, from among the multiple shielding elements, at least one shielding element is composed of a multi-ply Z-graded radiation shielding material in which multiple plies have different Z-values.

18. The camera of claim 10, wherein:
the first shielding element includes a first annular notch configured to connect to a corresponding second annular notch of second shielding element; and
the SCA is configured to detect infrared energy.

19. A method comprising:
providing multiple shielding elements configured to be enclosed within a housing assembly of a camera, the multiple shielding elements including:
a first shielding element including a window opening to pass light;
a second shielding element including a hole for a cold finger to pass through; and
a third shielding element;
placing a window housing member of the housing assembly over the first shielding element;
placing the first shielding element over a set of cold components of the camera, the set of cold components including a sensor chip assembly (SCA) for detecting the light;
placing the third shielding element under the SCA;
covering the hole of the second shielding element; and
installing the second shielding element under the third shielding element and in connection to the first shielding element to form a chamber within which the set of cold components is enclosed.

20. The method of claim 19, further comprising:
attaching the cold finger to the third shielding element;
placing a second member of the housing assembly under the second shielding element; and
attaching the second member to the window housing member;
wherein:
the set of cold components further includes a ceramic platform located under the SCA; and
installing the second shielding element under the third shielding element comprises installing the second shielding element under the ceramic platform.
